(19) United States
(12) Patent Application Publication
(10) Pub. No.: US 2010/0175743 A1
(43) Pub. Date: Jul. 15, 2010

(54) RELIABLE THIN FILM PHOTOVOLTAIC MODULE STRUCTURES

(75) Inventors: Pedro Gonzalez, Fremont, CA (US); Burak Metin, Milpitas, CA (US)

Correspondence Address: PILLSBURY WINTHROP SHAW PITTMAN LLP, P.O. BOX 10500, MCLEAN, VA, 22102, US

(73) Assignee: SOLOPOWER, INC., San Jose, CA (US)

(21) Appl. No.: 12/685,540

(22) Filed: Jan. 11, 2010

Related U.S. Application Data
(60) Provisional application No. 61/143,744, filed on Jan. 9, 2009.

(51) Int. Cl. H01L 31/048; H01L 31/00

(52) U.S. Cl. 136/251; 136/259

(57) ABSTRACT

The inventions described herein generally relate to photovoltaic or solar module design and fabrication and, more particularly, to modules utilizing thin film solar cells. In one aspect is described a solar module and method of making the same that has a shield material that is both an electrical insulator and a moisture barrier provided at a location corresponding to at least one hole that is used to route a wiring member, such that the shield material seals the at least one hole against moisture entering into the internal space and electrically insulates the wires of the wiring member from the at least one metallic layer of the back protective sheet.

### CROSS REFERENCE TO RELATED APPLICATION(S)

This application claims priority to U.S. Provisional Patent Application No. 61/143,744 filed Jan. 9, 2009 entitled “Reliable Thin Film Photovoltaic Modules Structures”, the entirety of which is incorporated by reference.

### FIELD OF THE INVENTIONS

The aspects and advantages of the present inventions generally relate to photovoltaic or solar module design and fabrication and, more particularly, to modules utilizing thin film solar cells.

### DESCRIPTION OF THE RELATED ART

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIAVIA compound semiconductors comprising some of the Group IB (Cu, Ag, Au), Group IIIA (B, Al, Ga, In, Tl) and Group VIA (O, S, Se, Te, Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ (S_{y}Se_{1-y})ₖ, where 0≦x≦1, 0≦y≦1 and k is approximately 2, have already been employed in solar cell structures that yielded conversion efficiencies approaching 20%. Therefore, in summary, compounds containing: i) Cu from Group IB, ii) at least one of In, Ga, and Al from Group IIIA, and iii) at least one of S, Se, and Te from Group VIA, are of great interest for solar cell applications. It should be noted that although the chemical formula for CIGS(S) is often written as Cu(In,Ga)(S,Se)₂, a more accurate formula for the compound is Cu(In,Ga)(S,Se)ₖ, where k is typically close to 2 but may not be exactly 2. For simplicity we will continue to use the value of k as 2. It should be further noted that the notation “Cu(X,Y)” in the chemical formula means all chemical compositions of X and Y from (X=0% and Y=100%) to (X=100% and Y=0%). For example, Cu(In,Ga) means all compositions from CuIn to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1.

The structure of a Group IBIIIAVIA compound photovoltaic cell such as a Cu(In,Ga,Al)(S,Se,Te)₂ thin film solar cell is shown in FIG. 1. A photovoltaic cell 10 is fabricated on a substrate 11, such as a sheet of glass, a sheet of metal, an insulating foil or web, or a conductive foil or web. An absorber film 12, which includes a material in the family of Cu(In,Ga,Al)(S,Se,Te)₂, is grown over a conductive layer 13 or contact layer, which is previously deposited on the substrate 11 and which acts as the electrical contact to the device. The substrate 11 and the conductive layer 13 form a base 20 on which the absorber film 12 is formed. Various conductive layers comprising Mo, Ta, W, Ti, and their nitrides have been used in the solar cell structure of FIG. 1. If the substrate itself is a properly selected conductive material, it is possible not to use the conductive layer 13, since the substrate 11 may then be used as the ohmic contact to the device. After the absorber film 12 is grown, a transparent layer 14 such as a CdS, ZnO, CdS/ZnO or CdS/ZnO/ITO stack is formed on the absorber film 12. Radiation 15 enters the device through the transparent layer 14. Metallic grids (not shown) may also be deposited over the transparent layer 14 to reduce the effective series resistance of the device. The preferred electrical type of the absorber film 12 is p-type, and the preferred electrical type of the transparent layer 14 is n-type. However, an n-type absorber and a p-type window layer can also be utilized. The preferred device structure of FIG. 1 is called a “substrate-type” structure. A “superstrate-type” structure can also be constructed by depositing a transparent conductive layer on a transparent superstrate such as glass or transparent polymeric foil, and then depositing the Cu(In,Ga,Al)(S,Se,Te)₂ absorber film, and finally forming an ohmic contact to the device by a conductive layer. In this superstrate structure light enters the device from the transparent superstrate side.

There are two different approaches for manufacturing PV modules. In one approach that is applicable to thin film CdTe, amorphous Si and CIGS technologies, the solar cells are deposited or formed on an insulating substrate such as glass that also serves as a back protective sheet or a front protective sheet, depending upon whether the device is “substrate-type” or “superstrate-type”, respectively. In this case the solar cells are electrically interconnected as they are deposited on the substrate. In other words, the solar cells are monolithically integrated on the single-piece substrate as they are formed. These modules are monolithically integrated structures. For CdTe thin film technology the superstrate is glass which also is the front protective sheet for the monolithically integrated module. In CIGS technology the substrate is glass or polyimide and serves as the back protective sheet for the monolithically integrated module. In monolithically integrated module structures, after the formation of solar cells which are already integrated and electrically interconnected in series on the substrate or superstrate, an encapsulant is placed over the integrated module structure and a protective sheet is attached to the encapsulant. An edge seal may also be formed along the edge of the module to prevent water vapor or liquid transmission through the edge into the monolithically integrated module structure.

In standard single or polycrystalline Si module technologies, and for CIGS and amorphous Si cells that are fabricated on conductive substrates such as aluminum or stainless steel foils, the solar cells are not deposited or formed on the protective sheet. They are separately manufactured and then the manufactured solar cells are electrically interconnected by stringing them or shingling them to form solar cell strings. In the stringing or shingling process, the (+) terminal of one cell is typically electrically connected to the (−) terminal of the adjacent device. For the Group IBIIIAVIA compound solar cell shown in FIG. 1, if the substrate 11 is conductive such as a metallic foil, then the substrate, which is the bottom contact of the cell, constitutes the (+) terminal of the device. The metallic grid (not shown) deposited on the transparent layer 14 is the top contact of the device and constitutes the (−) terminal of the cell. In shingling, individual cells are placed in a staggered manner so that a bottom surface of one cell, i.e. the (+) terminal, makes direct physical and electrical contact to a top surface, i.e. the (−) terminal, of an adjacent cell. Therefore, there is no gap between two shingled cells. In contrast, for solar cells that are strung together, solar cells are placed side by side with a small gap (typically 1-2 mm) between them and using conductive wires or ribbons that connect the (+) terminal of one cell to the (−) terminal of an adjacent cell. Solar cell strings obtained by stringing (or shingling) individual solar cells are interconnected through “busing” or “bussing” to form circuits. Circuits may then be packaged in a protective shell or package to seal the module. Each module typically includes a plurality of strings of solar cells which are electrically connected to one another. The two leads (the positive and negative leads) of the interconnected circuit are typically taken out through openings in the back protective sheet of the module structure and these leads are connected to terminals placed in a junction box on the back of the module.

FIG. 2A shows a top (illuminated side) view of a prior art module 200. FIG. 2B is a bottom view of the same module 200, while FIG. 2C is a cross sectional view taken across the line “2C-2C”. The module 200 has two solar cell strings 201A and 201B, each string containing six solar cells 210 strung together using conductive ribbons 211. The solar cell strings 201A, 201B, are electrically connected by buss conductors 202A, 202B and 202C. As shown in FIG. 2B, the back surface 203 of the module 200 (which is the same as the exposed surface of the back protective sheet 208) has a junction-box 204, within which two electrical terminals, 205B and 205C are located. The two terminals, 205B and 205C, are electrically connected to the buss conductors, 202B and 202C, respectively, and they constitute the two terminals of the module. For module structures employing CIGS type solar cells fabricated on metallic foil substrates, the terminal 205B is a (+) terminal and the terminal 205C is a (−) terminal of the module. As can be seen from FIGS. 2A and 2C, the module structure comprises a frame 206 (which is optional), a transparent front protective sheet 207, a back protective sheet 208 and an encapsulant layer 209 which is between the front protective sheet 207 and the back protective sheet 208 and surrounds the solar cell strings as well as the electrical connections and wirings in the module structure. A variety of materials may be used as encapsulant for packaging solar cell modules. These materials include ethylene vinyl acetate copolymer (EVA), thermoplastic polyurethanes (TPU), and silicones. An edge seal 209 may also be employed around the perimeter of the module to act as a moisture barrier. As can be seen from FIG. 2C, the bus conductors 202B and 202C are electrically connected to terminals 205B and 205C through two holes opened in the back protective sheet 208. It is also possible to have a single hole rather than two separate holes opened in the back protective sheet 208 for this purpose. The junction-box 204 is typically attached on the exposed surface 203 of the back protective sheet 208 using moisture barrier adhesives, and the holes in the back protective sheet 208 are sealed against water seepage using potting materials such as silicone, epoxy, and urethane containing materials. It should be noted that the placement of the junction-box 204 in PV modules may vary. For example, it is common to place the junction box on the back surface of the module right below the solar cells. This way, the size of the module is reduced and the frame is brought very close to the edges of the first solar cells near the edge.

The nature of the protective shell (which includes the front protective sheet 207, the back protective sheet 208, and optionally the edge seal 209 around the module perimeter) determines the amount of water or water vapor that can enter a module. Thin film solar cells are more moisture sensitive than the crystalline Si devices. Therefore, materials with moisture barrier characteristics need to be used in the module structure. The front protective sheet 207 is typically glass which is water impermeable. For flexible module structures employing thin film solar cells such as CIGS solar cells, thin, flexible and transparent polymeric sheets with moisture barrier coatings are used. For standard crystalline Si modules and monolithically integrated CdTe, CIGS and amorphous Si based modules the back protective sheet 208 may be a sheet of glass. For standard Si modules a polymeric sheet comprising a UV resistive material such as TEDLAR® (a product of DuPont) is also commonly used as the back protective sheet.

In rigid and flexible module structures employing thin film solar cells, it is important to minimize moisture permeability of the module structure while assuring that the structure passes the electrical safety tests necessary for safe operation in the field. From the foregoing, there is a need to develop solar module structures with minimum moisture permeability.

### SUMMARY

The inventions described herein generally relate to photovoltaic or solar module design and fabrication and, more particularly, to modules utilizing thin film solar cells.

In one aspect is described a solar module and method of making the same that has a shield material that is both an electrical insulator and a moisture barrier provided at a location corresponding to at least one hole that is used to route a wiring member, such that the shield material seals the at least one hole against moisture entering into the internal space and electrically insulates the wires of the wiring member from the at least one metallic layer of the back protective sheet.

In a particular aspect is described a solar module connectable to an external terminal, comprising: a protective shell including an internal space defined by a transparent front protective layer, a back protective layer and a moisture barrier seal extending between and sealing edges of the transparent front protective layer and the back protective layer, wherein the back protective sheet is a multilayer composite including at least one metallic layer and at least one insulator layer bonded to the at least one metallic layer, and wherein the back protective sheet includes at least one hole extending through the back protective sheet, between an inner surface and an outer surface thereof; at least one solar cell disposed within the internal space so that a light receiving side of the at least one solar cell faces the front protective layer and a back side of the at least one solar cell faces the back protective sheet; a wiring member for electrically connecting the at least one solar cell to the external terminal, wherein the wiring member is routed through the at least one hole formed through the back protective sheet, the wiring member including a first wire and a second wire; an encapsulant material that fills a remainder of the internal space and surrounds the at least one solar cell; and a shield material that is both an electrical insulator and a moisture barrier provided at a location corresponding to the at least one hole, such that the shield material seals the at least one hole against moisture entering into the internal space and electrically insulates each of the first wire and the second wire from the at least one metallic layer of the back protective sheet, wherein a water vapor transmission rate of the shield material is lower than the water vapor transmission rate of the encapsulant.

### BRIEF DESCRIPTION OF THE DRAWINGS

FIG. 1 is a schematic view a thin film solar cell;

FIG. 2A is a schematic top view of a prior art photovoltaic module;

FIG. 2B is a schematic bottom view of the module of FIG. 2A;

FIG. 2C is a schematic cross sectional view of the module of FIG. 2A, taken along the line 2C-2C;

FIG. 3 is a schematic cross sectional view of a back protective sheet and shielded leads according to an embodiment;

FIG. 4 is a schematic cross sectional view of a module including a junction box electrically connected to the module using the shielded leads; and

FIGS. 5A and 5B are schematic views of the structure of various shielded lead embodiments.

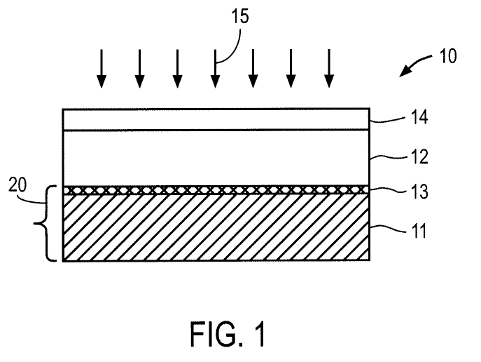

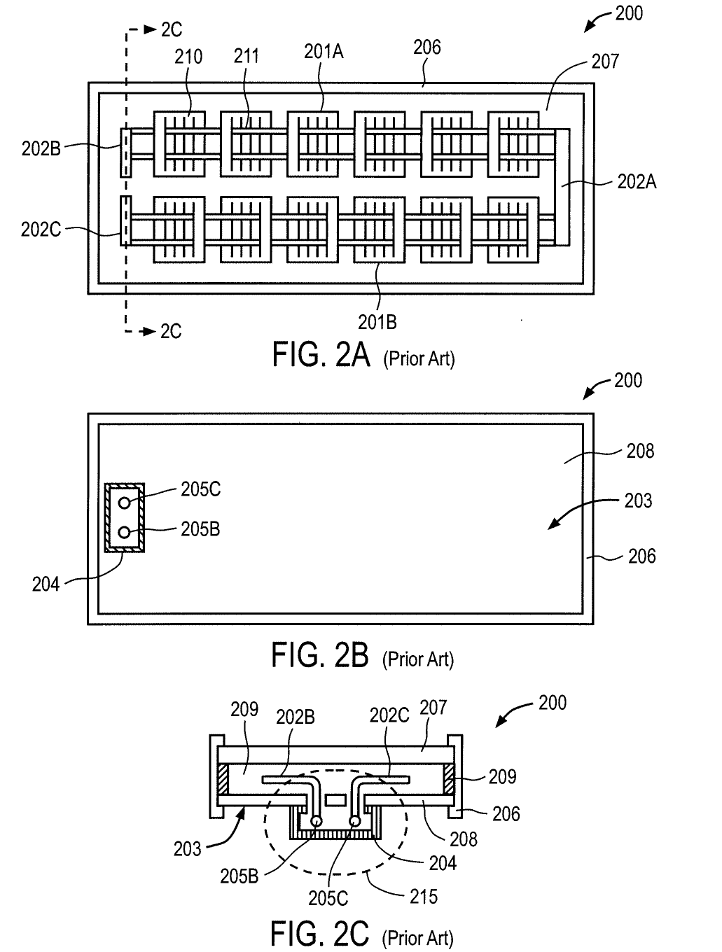

### DETAILED DESCRIPTION

The preferred embodiments described herein provide module structures and methods of manufacturing rigid or flexible photovoltaic modules employing thin film solar cells fabricated on flexible substrates, preferably on flexible metallic foil substrates. The solar cells may be Group IBIIIAVIA compound solar cells fabricated on thin stainless steel or aluminum alloy foils. The modules include a moisture resistant protective shell within which the interconnected solar cells or cell strings are packaged and protected. The moisture resistant protective shell comprises a top or front protective sheet through which the light enters the module, a back protective sheet, a support material or encapsulant covering at least one of a front side and a back side of each cell or cell string. The support material may preferably be used to fully encapsulate each solar cell and each string, top and bottom. The protective shell additionally comprises a moisture sealant that is placed between the front protective sheet and the back protective sheet along the circumference of the module and forms a barrier to moisture passage from outside into the protective shell from the edge area along the circumference of the module. The back protective sheet may be non-transparent and may comprise a composite structure, i.e., multiple layers stacked and bonded, including one or more metallic layers such as an aluminum layer to improve moisture resistance of the back protective sheet. The metallic layer may be interposed between polymeric layers such as TEDLAR® layers or TEDLAR and PET layers, or other polymeric material layers such as PVDF (poly vinyledene fluoride) or UV stabilized PET. The front protective sheet is typically a glass, but may also be a transparent flexible polymer film such as TEFZEL®, or another polymeric film such as Fluorinated ethylene propylene (FEP) or poly methyl methacrylate (PMMA). TEDLAR and TEFZEL are brand names of fluoropolymer materials from DuPont. TEDLAR is polyvinyl fluoride (PVF), and TEFZEL is ethylene tetrafluoroethylene (ETFE) fluoropolymer. In modules employing thin film devices, such as thin film CIGS solar cells, it is important that the back protective sheet to be a moisture barrier. Standard polymeric back sheets employing TEDLAR do not have the moisture barrier characteristics. The water vapor transmission rate (WVTR) for TEDLAR is 9-57 g/m²/day at 39.5° C. and 80% relative humidity. However, when a 18 to 50 um thick aluminum (Al) is laminated into the structure of such polymeric sheets, water vapor transmission rates of 10⁻³ g/m²/day or lower can be achieved. The front and back protective sheets may be flexible materials that have a water vapor transmission rate of less than 10⁻³ g/m²/day, preferably less than 5×10⁻⁴ g/m²/day. In one embodiment, for external connections, electrical leads of the solar cell strings are extended out of the solar module through one or more connection holes formed through the back protective sheet. Each electrical lead is at least partially coated by a protective shield layer which effectively seals the connection hole against moisture and electrically insulates the portions of the back sheet metallic layer which may be exposed when the connection hole is formed.

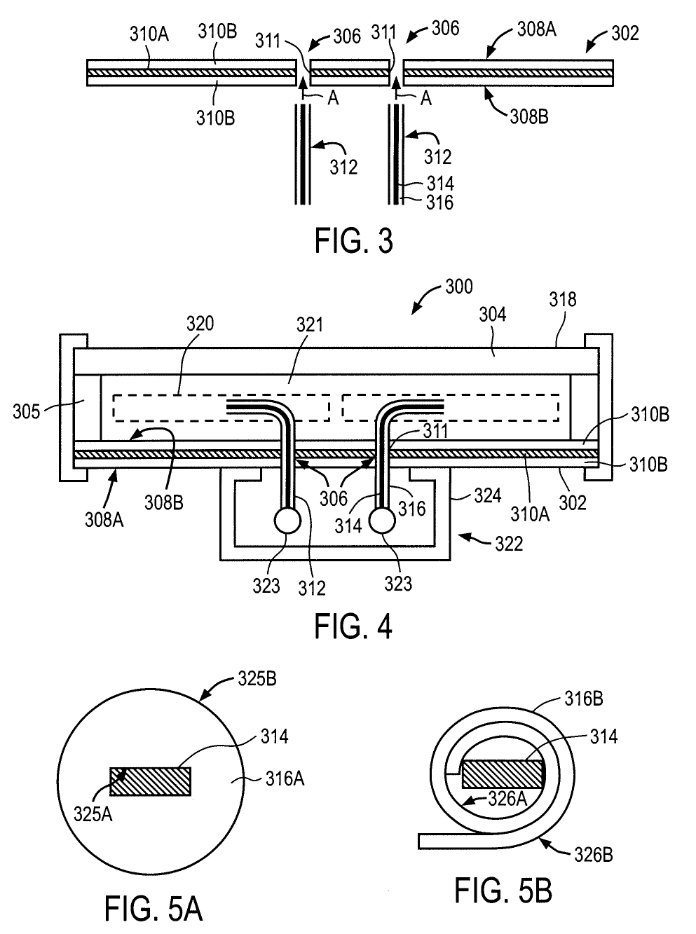

An embodiment of the present invention will now be described in connection to FIGS. 3 and 4. FIG. 3 shows a cross sectional view of a back protective sheet 302 including connection holes 306 extending from a first surface 308A to a second surface 308B. As will be described below the back protective sheet may be a component of an exemplary solar module shown in FIG. 4. The first surface 308A faces the outside and the second surface 308B faces the inside of a module when the module is manufactured. The back protective sheet 302 may have a composite structure including a metallic layer 310A such as an aluminum layer. The metallic layer 310A may be interposed between polymeric layers 310B such as TEDLAR layers. When the connection holes 306 are formed, edge portions 311 of the metallic layer 310A are exposed, as explained above. The shielded leads 312 are placed in the direction of the arrows ‘A’ and fitted into the connection holes 306 so as to form a moisture seal and to electrically insulate the edge portions 311 within the connection holes 306. Each shielded lead 312 includes an electrical lead 314 or a conductive wire, e.g., copper ribbon, and a shield layer 316 or shield film surrounding or coating it. The shield layer 316 may have dielectric strength in the range of 500-10000 V/mil, typically 1000-6000, and preferably greater than 4000 V/mil. A volume resistivity for the shield layer 316 may be in the range of 10¹⁴-10¹⁹ ohm.cm, typically 10¹⁵-10¹⁹ ohm.cm, and preferably equal to or greater than 10¹⁸ ohm.cm. A water vapor transmission rate of the shield layer 316 may be in the range of 0.1-22 g/m²/day, typically, 1-15 g/m²/day, and preferably less than 5 g/m²/day.

The electrical leads 314 connect solar cells to various external electrical terminals outside the exemplary module 300 shown in FIG. 4. The length of the shield layer 316 surrounding the electrical lead 314 may be at least equal to the depth of the connection holes 306 so that the edge portions 311 of the metallic layer 310A within the connection holes 306 are electrically insulated and the connection holes 306 are sealed against moisture. The thickness of the shield layer 316 may be 4 mil (0.1 mm) to 40 mil (1 mm) for a 3 mm wide hole in the protective back sheet.

As shown in FIG. 4, in side view, the solar module 300 includes a front protective sheet 304, which is light transparent, and the back protective sheet 302 described above. The shielded leads 314 are placed into the connection holes 306 formed through the back protective sheet to electrically insulate the edge portions 311 and moisture-seal the connection holes 306. The module 300 further comprises an edge seal 305 extending between the front protective sheet 304 and the back protective sheet 302 and sealing the edges of them. The back protective sheet 302, the front protective sheet 304 and the edge seal 305 form a protective shell 318 which protects an exemplary solar cell string 320 or strings contained therein from moisture and other corrosive elements. The solar cells may be Group IBIIIAVIA (CIGS) compound solar cells fabricated on thin stainless steel or aluminum alloy foils, amorphous silicon thin film solar cells, CIS thin film solar cells or CdTe solar cells. The solar cells in the solar cell string 320 may be connected in series. Although the module 300 includes a string of interconnected solar cells in this example, the module 300 may include a single solar cell as well. A support material 321 or encapsulant material, such as ethylene vinyl acetate (EVA) and/or thermoplastic polyurethane (TPU), fills the space between the solar cell strings 320 and the protective shell 318. The support material 321 may also include thermoplastic olefins, pressure sensitive silicone or acrylic adhesives. The electrical leads 314 are connected to the solar cell strings 320 using methods which are well known in the solar cell manufacturing technologies. A junction box 322 including terminals 323 may be attached to the first surface 308A of the back protective sheet 302, may be sealed by a moisture barrier. A housing 324 of the junction box 322 encloses the connection holes 306. The shielded leads 312 including the electrical leads 314 coated by the protective shield layer 316 are connected to the terminals 323 in the junction box 324. In one embodiment, the back protective sheet may have a single connection hole, and the shielded leads are formed as a wiring member (not shown) routed through the single connection hole.

The protective shield layers 316, which may partially or fully covers the electrical leads and may be made of a high dielectric strength and moisture resistant materials, are placed through the connection holes in a tightly fitting manner so as to minimize any moisture leakage inside the module. Exemplary materials for the protective shield layer 316 may be the following materials: polyethylene terephthalate (PET), which is available under the commercial names Mylar®, Melinex®, heat shrink Mylar; polyimide (Kapton®); polyolefins (EPS 300); and polyethylene napthalate (PEN).

The dimensions of the connection holes 306 formed through the back protective sheet may for example be about 0.45-2.3 mm wide and 5.2-7 mm long. The electrical lead wires are usually about 5 mm wide and about 0.25 to 0.30 mm thick. In a prior art module with no shield layers around the electrical leads, the lead wires are surrounded with an encapsulant material EVA or TPU with WVTR of 35 and 25 g/m²/day, respectively. However, PET, PEN and polyimide layers used as shield layers usually have WVTR of 3-15 g/m²/day, 0.9-6 g/m²/day and 0.4-21 g/m²/day, respectively, which are much lower than EVA and TPU encapsulants. Such shield layers minimize moisture transport through the connection holes 306. If the thickness of the shield layer 316 is adjusted right with respect to the connection hole size, there will be less of an encapsulant-containing area inside the connection holes. With the thickness adjustment, the shield layer 316 may protect the solar module from moisture better than when there is none. For example, the thickness of the shield layer may be 4 mil (0.1 mm) to 40 mil (1 mm) for a 0.45-2.3 mm wide connection hole in the back protective sheet 302 (FIGS. 3 and 4). A shield layer with 40 mil thickness can protect the panel from moisture better than a thinner shield layer. Of course, the same shielded lead may be inserted into a smaller connection hole in a tight fitting manner by compressing the shield layer. The gain in moisture barrier performance is significant since the shield layer materials have better WVTR than the encapsulants.

The shield layer containing the electrical lead may also prevent a high voltage shorting between the conductive metallic layer in the back sheet and the solar cells. For example, PET films usually have dielectric strength greater than 4000 V/mil. A heat shrink PET tubing, which is available from Advanced Polymers Inc., (Salem, N.H.), has a dielectric strength greater than 4000 V/mil and volume resistivity on the order of 10¹⁸ ohm-cm. PEN films, such as TEONEX from Dupont, have a dielectric strength greater than 5000 V/mil and a volume resistivity of about 10¹⁸ ohm-cm. Various polyimide formulations, which are available from Dupont, can provide dielectric strengths greater than 4000 V/mil, such as BCL-Y (4500 V/mil), FPC and HPP-ST (7,700 V/mil for 1 mil thickness). Other polyimide, polyolefin, PET, and PEN films under various commercial names may also be used as the shield layer around the electrical leads. The electrical insulation, which is applied to the above defined exposed portions of the metallic layer by the protective shield, is especially important when the solar module is used in high voltage systems, such as a system that connects modules in series to build the voltage up to the 600-1500V range. It should be noted that the typical voltage of a module is in the range of 14-60 V and the above mentioned shorting issue is not significant at these low voltages when a single module is operated by itself.

At such high voltages, if a high dielectric strength shield layer is not used to coat the electrical leads, there may be electrical arcing between the unprotected electrical leads, and the metallic layer through the exposed edges of the metallic layer, even though in the prior art the holes are usually filled with an encapsulant or a potting material as explained in the back ground section. Such encapsulant or potting materials do not have the 1000V electrical insulation rating to stop such electrical arcing. One prior art solution to this arcing problem is making the connection holes sufficiently large to minimize or avoid electrical arcing between the unprotected lead and the exposed metallic layer. In this approach, the holes must be large so that the unprotected lead is radially at least 15-20 mm away from the lead portion in the connection hole. However, such large holes may allow moisture to enter the module and cause malfunction.

FIGS. 5A and 5B show the structure of shielded leads. FIG. 5A is a cross sectional view of an embodiment of a shielded lead taken along the width or diameter of the shielded lead. In FIG. 5A, the electrical lead is placed into a tube shield 316A. An inner surface 325A and an outer surface 325B of the shield tube 316A may include adhesives to attach the electrical lead 314 to the inner surface 325A and the outer surface 325B to the connection hole 306. As shown in FIG. 5B in another embodiment a sheet shield 316B may be wrapped around the electrical lead 314 to form another shielded lead. An inner surface 326A and an outer surface 326B of the sheet shield 316B may also include adhesives to wrap it around the electrical lead and to attach the connection hole 306. Although FIGS. 5A and 5B show shield layers having round shape, they may have other possible shapes. Specifically, the shields layers may have flat shape and conformally surround the electrical leads 314.

Although aspects and advantages of the present inventions are described herein with respect to certain preferred embodiments, modifications of the preferred embodiments will be apparent to those skilled in the art.

We claim:

1. A solar module connectable to an external terminal, comprising:
a protective shell including an internal space defined by a transparent front protective layer, a back protective layer and a moisture barrier seal extending between and sealing edges of the transparent front protective layer and the back protective layer, wherein the back protective sheet is a multilayer composite including at least one metallic layer and at least one insulator layer bonded to the at least one metallic layer, and wherein the back protective sheet includes at least one hole extending through the back protective sheet, between an inner surface and an outer surface thereof;
at least one solar cell disposed within the internal space so that a light receiving side of the at least one solar cell faces the front protective layer and a back side of the at least one solar cell faces the back protective sheet;
a wiring member for electrically connecting the at least one solar cell to the external terminal, wherein the wiring member is routed through the at least one hole formed through the back protective sheet, the wiring member including a first wire and a second wire;
an encapsulant material that fills a remainder of the internal space and surrounds the at least one solar cell; and
a shield material that is both an electrical insulator and a moisture barrier provided at a location corresponding to the at least one hole, such that the shield material seals the at least one hole against moisture entering into the internal space and electrically insulates each of the first wire and the second wire from the at least one metallic layer of the back protective sheet, wherein a water vapor transmission rate of the shield material is lower than the water vapor transmission rate of the encapsulant.

2. The solar module of claim 1 further comprising a junction box in which the external terminal is located, wherein the junction box is attached to the outer surface of the back protective sheet.

3. The solar module of claim 1, wherein the at least one hole comprises a first hole and a second hole so that the first wire extends through the first hole and the second wire extends through the second hole, and wherein the shield material is disposed at each of the first hole and second hole locations and seals each of the first hole and the second hole against moisture entering into the internal space and electrically insulates each of the first wire and the second wire from the at least one metallic layer of the back protective sheet.

4. The solar module of claim 1, wherein the shield material is shaped as a tube around each of the first and second wires.

5. The solar module of claim 1, wherein the shield material is an adhesive strip wrapped around each of the first and second wires.

6. The solar module of claim 1, wherein the front protective layer comprises one of glass and ETFE (ethylene tetrafluoroethylene).

7. The solar module of claim 7, wherein the at least one polymer layer of the back protective layer comprises PVF (polyvinyl fluoride) and the at least one metallic layer comprises aluminum.

8. The solar module of claim 7, wherein the light receiving side of each solar cell includes one of a Group IBIIIAVIA thin film, an amorphous silicon thin film and a CdTe thin film.

9. The solar module of claim 8, wherein the encapsulant material comprises one of ethylene vinyl acetate (EVA), thermoplastic polyurethane (TPU), thermoplastic olefin, pressure sensitive silicone and acrylic adhesive.

10. The solar module of claim 9, wherein the shield material is one of polyethylene terephthalate (PET), polyimide, poly ethylene napthalate (PEN), and polyolefin.

11. The solar module of claim 10, wherein the dielectric strength of the shield material is at least 4000 V/mil.

12. The solar module of claim 11, wherein the volume resistivity of the shield material is at least 10¹⁸ ohm-cm.

13. The solar module of claim 1 wherein the shield material is disposed within at least 50% of the length of the through hole.

14. The solar module of claim 1, wherein the at least one solar cell comprises a plurality of interconnected solar cells.

15. The solar module of claim 1, wherein the front protective layer comprises one of glass ETFE (ethylene tetrafluoroethylene), fluorinated ethylene propylene (FEP) and poly methyl methacrylate (PMMA).

16. The solar module of claim 1, wherein the at least one polymer layer of the back protective layer comprises one of PVF (polyvinyl fluoride), PVDF (poly vinyledene fluoride) and UV stabilized PET, and the at least one metallic layer comprises aluminum.

17. The solar module of claim 1, wherein the light receiving side of each solar cell includes one of a Group IBIIIAVIA thin film, an amorphous silicon thin film and a CdTe thin film.

18. The solar module of claim 1, wherein the encapsulant material comprises one of ethylene vinyl acetate (EVA), thermoplastic polyurethane (TPU), thermoplastic olefin, pressure sensitive silicone and acrylic adhesive.

19. The solar module of claim 1, wherein the shield material is one of polyethylene terephthalate (PET), polyimide, poly ethylene napthalate (PEN), and polyolefin.

20. The solar module of claim 1, wherein the dielectric strength of the shield material is at least 4000 V/mil.

21. The solar module of claim 1, wherein the volume resistivity of the shield material is at least 10¹⁸ ohm-cm.

22. The solar module of claim 1, wherein the water vapor transmission rate of the shield material is less than 5 g/m²/day.
